(19) United States
(12) Patent Application Publication
(10) Pub. No.: US 2016/0305992 A1
(43) Pub. Date: Oct. 20, 2016

(54) SMART POWER PLUG INTEGRATED WITH A WIRELESS CONTROL SYSTEM

(71) Applicant: DAWON DNS, Kwangmyungsi (KR)

(72) Inventor: Un Nam Yeo, Kwangmyungsi (KR)

(21) Appl. No.: 15/098,693

(22) Filed: Apr. 14, 2016

Related U.S. Application Data
(60) Provisional application No. 62/148,754, filed on Apr. 17, 2015.

(51) Int. Cl. G01R 22/06; H01R 24/20; H04W 4/00; H01R 13/66

(52) U.S. Cl. CPC G01R 22/063; H01R 13/6666; H01R 24/20; H04W 4/008; H04W 84/12

(57) ABSTRACT

A smart power plug integrated with a wireless control system for controlling and monitoring an electrical device is provided. The smart power plug has a housing for said wireless control system with first and second ends, wherein the first end includes a male power plug configured to be plugged in an electrical power outlet for electrical connection to a power source and the second end receives a power cord with a proximal end and a distal end. The distal end is configured to be connected to the electrical device.

### CROSS-REFERENCE TO RELATED APPLICATION

This application claims the benefit of U.S. Prov. Pat. App. No. 62/148,754, filed on Apr. 17, 2015, herein incorporated by reference in its entirety.

### FILED OF INVENTION

This invention relates to an integrated apparatus having a wireless control of and monitoring electrical usages or status of, via a user mobile device, an electrical system connected to the integrated apparatus and a method of controlling or monitoring usages or status of, via a user mobile device, an electrical system connected to the integrated apparatus.

### SUMMARY OF INVENTION

According to one embodiment, a smart power plug integrated with a wireless control system for controlling and monitoring an electrical device is provided. The smart power plug has a housing for said wireless control system with first and second ends, wherein the first end includes a male power plug configured to be plugged in an electrical power outlet for electrical connection to a power source and the second end receives a power cord with a proximal end and a distal end. The distal end is configured to be connected to the electrical device.

The wireless control system includes a micro controller unit (MCU), which is connected to a relay control circuit and a wireless network module. The relay control circuit is configured to control an electrical connection between the power source and the electrical device. The wireless network module allows wireless communication between the smart power plug and an outside communication contact point such as a network server, modem, mobile phone, personal computer, or other communication device. The wireless network module encrypts and modulates information received from the MCU before transferring the information to the outside communication contact point and communicates an operational instruction received from the outside communication contact point to the MCU.

The wireless control system includes an AC-DC converting circuit that converts AC electricity received through the first terminal from an outside power source such as a power outlet to DC power, which is used to power the MCU and the wireless network module. The smart power plug can be used to wireless control the power connection to the electrical device to which the power plug is connected.

The smart power plug may include a measuring chip for measuring power usage information of said electrical device wherein said measured information is communicated to MCU and to outside communication contact point. The measuring chip measures electrical current used by the electrical device at least 2500 times per second, preferably at least 4000 times per second.

The wireless communication uses a short range communication protocol such as ANT+, Bluetooth, Cellular, IEEE 802.15.4, IEEE 802.22, ISA 100a, Infrared (IrDA). ISM band, NFC, RFID, 6LoWPAN, UWB, Wi-Fi, Wireless HART, WirelessHD, WirelessUSB, Zigbee or Z-Wave.

The smart power plug may have a surge protection circuit configured to protect the wireless control system from power surge from said power source and a zero crossing circuit configure to control timing of the electrical connection control by the relay control circuit.

The smart power plug may have one or more communication cable which can be used to connect the wireless control system with an electrical device to which the smart power plug is connected. The communication cable may be connected to a serial communication unit configured to communicate with a control unit of said electrical device through said communication cable. There may be an isolation unit between said serial communication unit and said MCU. The distal end of the power cord may be connected to a female power plug and a UBS plug or a female power plug integrated with a communication port so that the smart power plug can be connected to an electrical device by plug-in. 12. Many different electrical devices including water heating matts can be used with the smart power plug.

A smart light bulb socket adopter integrated with a wireless control system has an upper housing with a male threaded portion for insertion into and electrical contact with a light bulb socket of a light fixture; and a lower housing having a female threaded portion for receiving and electrical contact with a light bulb. The wireless control system is disposed between said upper and lower housings and is electrically connected to said male threaded portion and said female threaded portion. The wireless control system has a micro controller unit (MCU) connected to a relay control circuit and a wireless network module. The relay control circuit is configured to control electrical connection between said male threaded portion and said female threaded portion.

The wireless network module enables wireless communication between the smart light bulb socket adopter and an outside communication contact point. The wireless network module is configured to encrypt and modulate information received from said MCU and to communicate operational instruction to said MCU.

The wireless control system is powered with DC power. An AC-DC converting circuit is deposed within the housing and configured to convert AC electricity received from said first terminal to DC power, which is provided to the MCU and the wireless network module.

The smart light bulb socket adopter is configured to wirelessly control the electrical connection to the light fixture so that a user can turn the light fixture using a mobile phone

The smart light bulb socket may have a measuring chip for measuring power usage information of said electrical device wherein said measured information is communicated to MCU. Based on the measurement, the smart light bulb socket determines the condition of the light bulb.

The measuring chip measures electrical current used by the electrical device at least 2500 times per second, preferably at least 4000 times per second.

The smart light bulb socket adopter may include a surge protection circuit configured to protect a power surge from said power source and a zero crossing circuit configure to control timing of the electrical connection control by said relay control circuit.

### BRIEF DESCRIPTION OF THE DRAWINGS

FIG. 1 depicts a perspective view of the plug portion of a smart power cord integrated with a wireless control system according to an embodiment of the present invention

FIG. 2. illustrates wireless communication between a mobile device and an embodiment of the present invention

FIG. 3 depicts a female end of a power cord with an UBS connector according to an embodiment of the present invention.

FIG. 4 illustrates an embodiment of the present invention with an UBS connector.

FIG. 5 illustrates an embodiment of the present invention with a female power cord plug integrated with a communication port.

FIG. 6 illustrates an embodiment of the present invention where a smart power cord is connected to a heating matt.

FIG. 7 illustrates an embodiment of the present invention where the male plug is separable from the housing for a wireless control system. In this system, the wireless control system can be easily incorporated with different types of male plugs used in different countries.

FIG. 8 illustrates an embodiment of the present invention.

FIG. 9 shows a block diagram for an embodiment of the present invention. Some on the components shown in the block diagram can be omitted depending on needs.

FIG. 10 depicts an embodiment of a smart light bulb socket with an integrated wireless control system according to an embodiment of the present invention. The light bulb shown is not a part of the invention. The smart light bulb socket can be wirelessly controlled by a user using a smart phone.

FIG. 11 depicts a smart light bulb socket with an integrated wireless control system according to an embodiment of the present invention with illustration of the inside components.

FIG. 12 depicts an exploded view of an embodiment of a smart light bulb socket with an integrated wireless control system according to an embodiment of the present invention.

FIG. 13 shows a block diagram for an embodiment of the present invention. Some on the components shown in the block diagram can be omitted depending on needs.

### PREFERRED EMBODIMENTS OF THE INVENTION

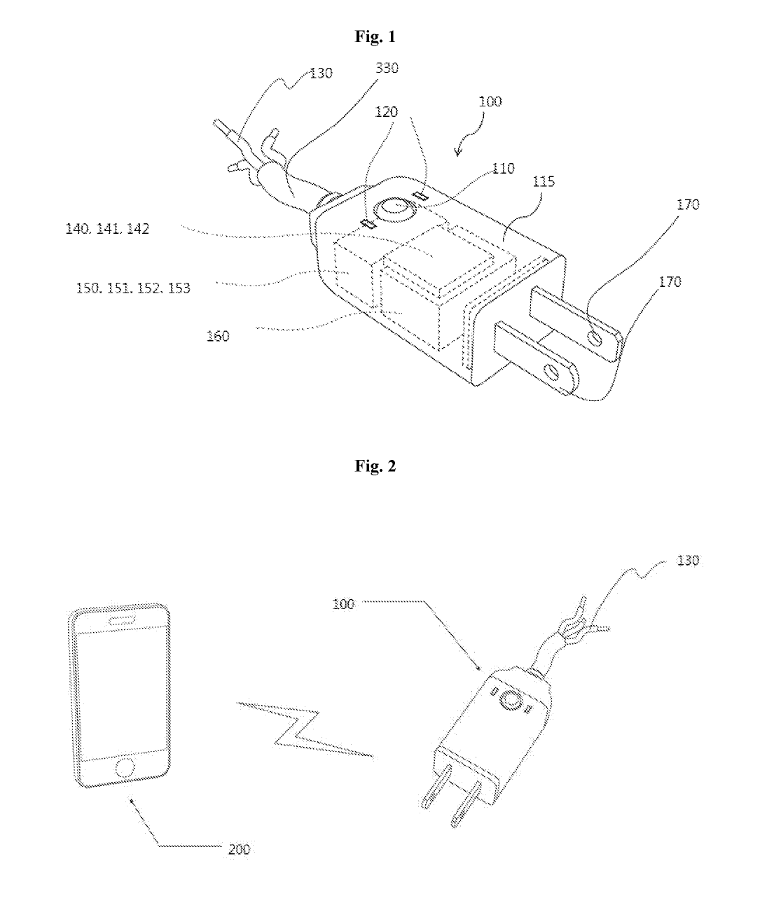

In FIG. 1, a smart power plug according to an embodiment of the present invention is provided. The smart power plug integrated with a wireless control system (100) includes a housing (115) for the wireless control system with first and second ends, where the first end includes a male power plug (170) configured to receive electrical power from a power source and the second end receives a power cord (130) with a proximal end and a distal end. The distal end is configured to be connected to an electrical device. The wireless control system includes a micro controller unit (MCU, 140) connected to a relay control circuit (160) and a wireless network module (141) where the relay control circuit is configured to control electrical connection between the power source and the electrical device such as appliances. The wireless network module enables wireless communication between the smart power plug and an outside communication contact point such as a server, router, or a mobile phone. The wireless network module is configured to encrypt and modulate information received from said MCU and to communicate operational instruction to said MCU. Different types of communication protocols including ANT+, Bluetooth, Cellular, IEEE 802.15.4, IEEE 802.22, ISA 100a, Infrared (IrDA). ISM band, NFC, RFID, 6LoWPAN, UWB, Wi-Fi, Wireless HART, WirelessHD, WirelessUSB, Zigbee, Z-Wave and other short range communication protocols can be used.

An AC-DC converting circuit (151) is included to convert AC electricity received from said first terminal to DC power, which provides power to the MCU and the wireless network module.

The smart power plug can also include various sensors such as a measuring chip (152), which measures and monitor power use of an electrical device connected to the smart power plug. Measured data is communicated to the MCU and then to a server or/and a user's mobile phone depending on its service set up as depicted in FIG. 2.

The housing can have a reset button (110) and LED status lights (120).
[1] The smart power plug measures electrical current used by the electrical device at least 2500 times per second, preferably 4000 times per second.

The smart power plug can further include a surge protection circuit (150) configured to protect a power surge from the power source and a zero crossing circuit (153) configured to control timing of the electrical connection control by the relay control circuit.

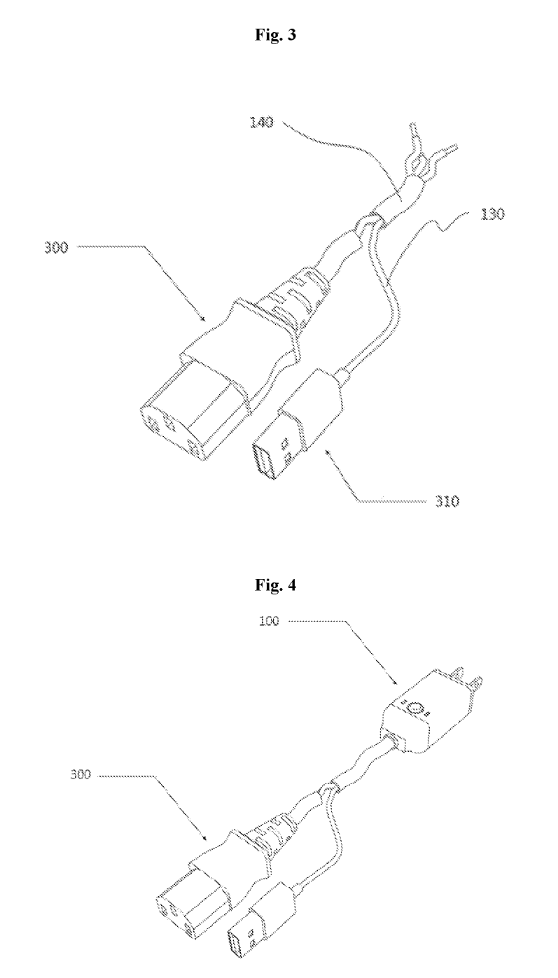

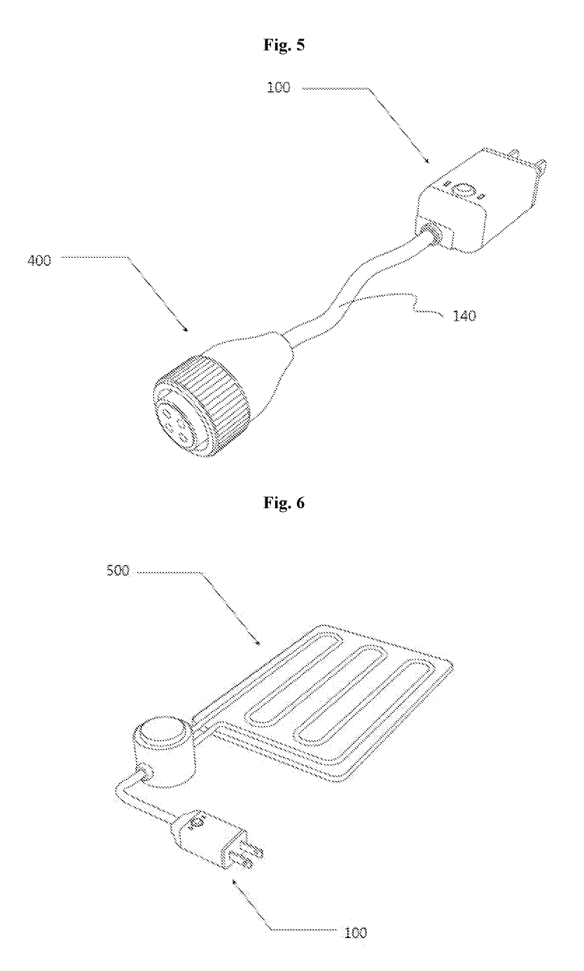

The power cord can include one or more communication cable in addition to power lines. The communication cable at its distal end may be connected to a serial communication unit which communicate with a control unit of said electrical device through the communication cable. An isolation unit can be provided between the MCU and the serial communication unit to prevent any unwanted surge back from the electrical device to the MCU. The power cord can be connected to a female power plug (300) and a UBS plug (310) or a female power plug integrated with a communication port (400) as shown in FIGS. 3-5.

Another embodiment of the present invention depicted in FIG. 6 provides a heating matt (500) utilizing water as heating medium where the matt control unit is connected to a smart power plug (100) according to the present invention. Through the smart power plug, a user is able to wireless control the matt, e.g., turning on or off, changing temperature setting, or setting timer and to measure electricity consumption with the user's mobile phone or computer. The heating matt can have a water pump but may be operable without a water pump. The matt control unit include a heating unit to heat water to a preset temperature. The matt control unit could have a cooling unit to cool water to achieve a lower temperature, for example, during summer.

In other embodiment, a smart power plug (600) integrated with a wireless control unit has a housing for the wireless control unit with first and second ends, where the first end is connected to a male power plug (610) configured to receive electrical power from a power source via electrical wires and the second end is connected to a power cord with a proximal end and a distal end. The distal end is configured to be connected to an electrical device. The wireless control unit includes a micro controller unit (MCU) connected to a relay control circuit and a wireless network module. The relay control circuit configured to control electrical connection between the power source and the electrical device. The wireless network module for wireless communication between the smart power plug and an outside communication contact point. The wireless network module is configured to encrypt and modulate information received from said MCU and to communicate an operational instruction received from the outside communication contact point to the MCU.

An AC-DC converting circuit converts AC electricity received from the first terminal to DC power, which powers the MCU and the wireless network module. The smart power plug can include a measuring chip, e.g., for measuring power usage information of the electrical device wherein the measured information is communicated to MCU. A serial communication unit is figured to be electrically connected to a control unit of said electrical device through the communication cable where the serial communication unit allows the MCU to control based on said instruction information received from the wireless network module. An isolation unit can be used between said serial communication unit and said MCU.

The distal end of said power cord can be electrically connected to a female power plug and a UBS plug or a female power plug integrated with a communication port.

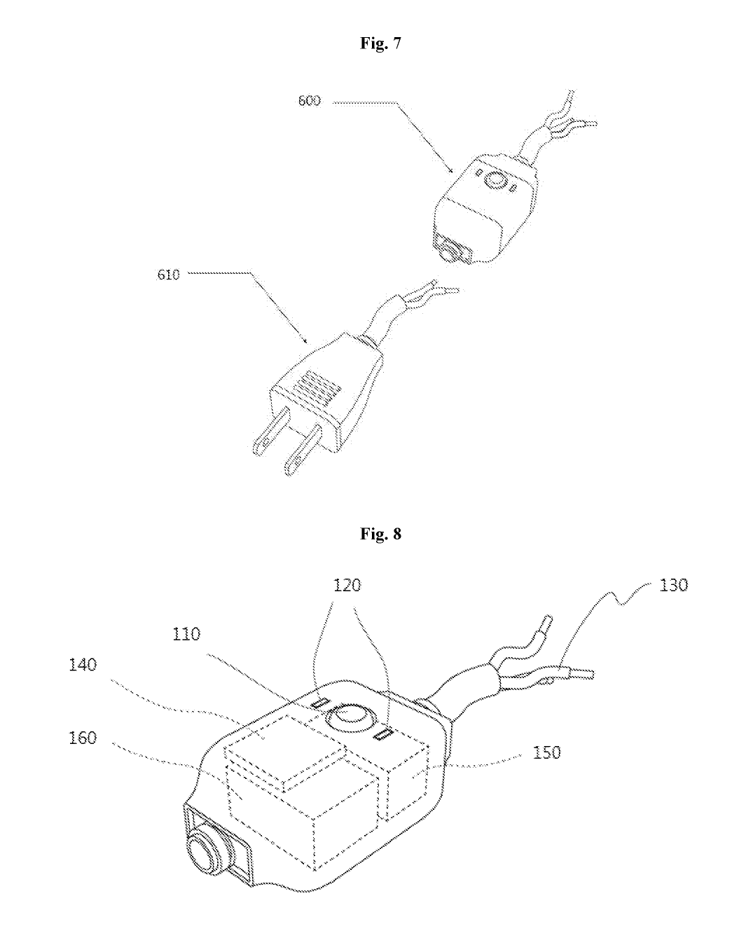

In another embodiment, a smart power plug having a housing (600) for a wireless control system and another housing for a male plug (610) as shown in FIG. 7. The male plug is connected through electrical wire. The wireless control system shown in FIG. 8 includes a micro controller unit (MCU, 140) connected to a relay control circuit (160) and a wireless network module where the relay control circuit is configured to control electrical connection between the power source and the electrical device such as appliances. The wireless network module enables wireless communication between the smart power plug and an outside communication contact point such as a server, router, or a mobile phone. The wireless network module is configured to encrypt and modulate information received from said MCU and to communicate operational instruction to said MCU. Different types of communication protocols including ANT+, Bluetooth, Cellular, IEEE 802.15.4, IEEE 802.22, ISA 100a, Infrared (IrDA). ISM band, NFC, RFID, 6LoWPAN, UWB, Wi-Fi, Wireless HART, WirelessHD, WirelessUSB, Zigbee, Z-Wave and other short range communication protocols can be used.

An AC-DC converting circuit is included to convert AC electricity received from said first terminal to DC power, which provides power to the MCU and the wireless network module.

The smart power plug can also include various sensors such as a measuring chip, which measures and monitor power use of an electrical device connected to the smart power plug. Measured data is communicated to the MCU and then to a server or/and a user's mobile phone depending on its service set up.

The housing can have a reset button (110) and LED status lights (120).

The smart power plug measures electrical current used by the electrical device at least 2500 times per second, preferably 4000 times per second.

The smart power plug can further include a surge protection circuit (150) configured to protect a power surge from the power source and a zero crossing circuit configured to control timing of the electrical connection control by the relay control circuit.

The power cord can include one or more communication cable in addition to power lines. The communication cable at its distal end may be connected to a serial communication unit which communicate with a control unit of said electrical device through the communication cable. An isolation unit can be provided between the MCU and the serial communication unit to prevent any unwanted surge back from the electrical device to the MCU. The power cord can be connected to a female power plug and a UBS plug or a female power plug integrated with a communication port.

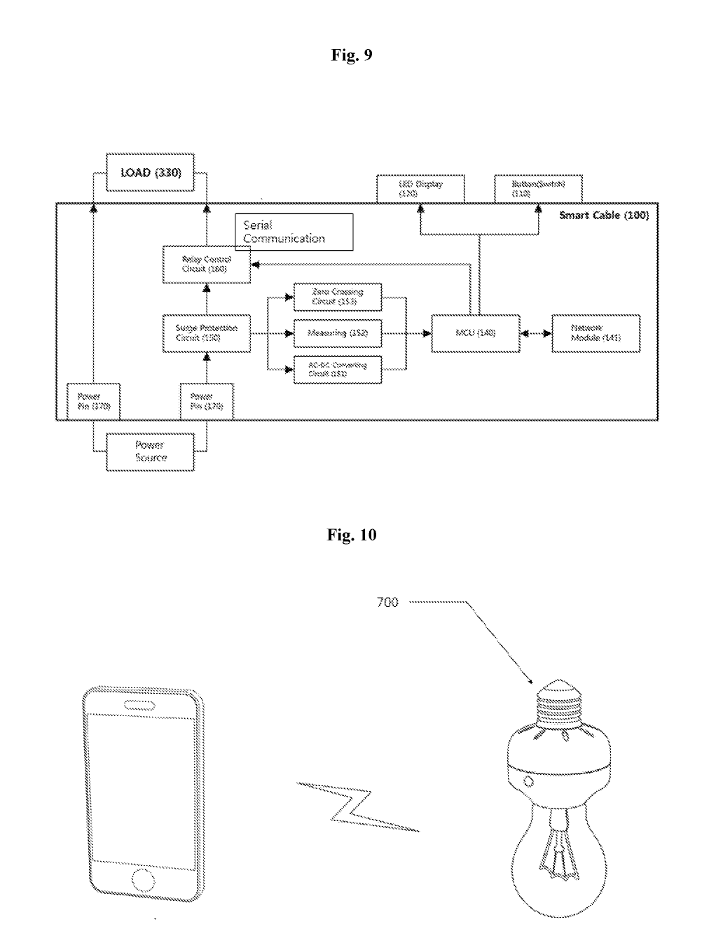

FIG. 9 illustrates electrical connections of various components used in a smart power plug according to one embodiment of the present invention.

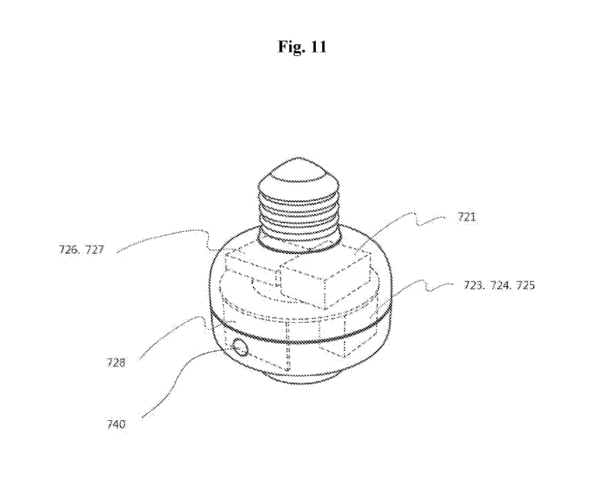

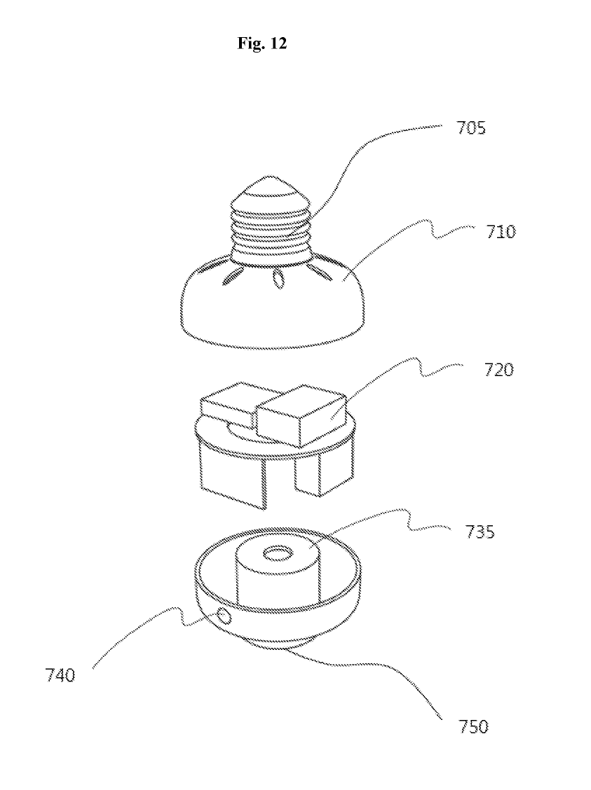

FIGS. 10-12 illustrate an another embodiment, a smart light bulb socket adopter (700) integrated with a wireless control system includes a upper housing (710) having a male threaded portion (705) for insertion into and electrical contact with a light bulb socket of a light fixture and a lower housing (750) having a female threaded portion (735) for receiving and electrical contact with a light bulb wherein the wireless control system disposed between the upper and lower housings is electrically connected to the male threaded portion and the female threaded portion. The wireless control system includes a micro controller unit (MCU, 726) connected to a relay control circuit (721) and a wireless network module (727). The relay control circuit (721) is configured to control electrical connection between said male threaded portion and the female threaded portion. The wireless network module for wireless communication between the smart light bulb socket adopter and an outside communication contact point. The wireless network module is configured to encrypt and modulate information received from said MCU and to communicate operational instruction to said MCU. An AC-DC converting circuit (723) is configured to convert AC electricity received from the first terminal to DC power, which is provided to the MCU and the wireless network module. The smart light bulb socket adopter is configured to wirelessly control and measure the electrical connection to the light fixture.

The smart light bulb socket adopter may include a measuring chip (724) for measuring power usage information of said electrical device wherein said measured information is communicated to MCU. The measuring chip measures electrical current used by the electrical device at least 2500 times per second, preferably at least 4000 times per second.

The lower housing may have a status light and a reset button.

The smart light bulb socket adopter may include a surge protection circuit configured to protect a power surge from said power source and a zero crossing circuit (725) configure to control timing of the electrical connection control by said relay control circuit.

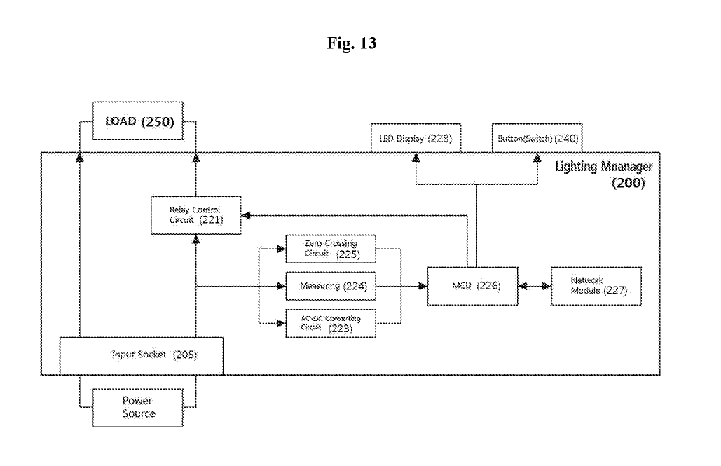

FIG. 13 illustrates electrical connections of various components used in a smart light bulb socket adopter according to one embodiment of the present invention.

Since the above embodiments are described only for examples, the present invention is not limited to the above embodiments and various modifications or alterations can be easily made therefrom by those skilled in the art without departing from the scope of the present invention.

What is claimed is:

1. A smart power plug integrated with a wireless control system for controlling and monitoring an electrical device, comprising
a housing for said wireless control system with first and second ends, wherein said first end includes a male power plug configured to be plugged in an electrical power outlet for electrical connection to a power source and said second end receives a power cord with a proximal end and a distal end, said distal end configured to be connected to said electrical device; and said wireless control system comprising
a micro controller unit (MCU) connected to a relay control circuit and a wireless network module wherein said relay control circuit configured to control electrical connection between said power source and said electrical device and said wireless network module allows wireless communication between said smart power plug and an outside communication contact point, encrypting and modulating information received from said MCU to transfer to the outside communication contact point and communicating an operational instruction received from the outside communication contact point to said MCU; and
an AC-DC converting circuit configured to convert AC electricity received from said first terminal to DC power, which is provided to said MCU and said wireless network module wherein said smart power plug is configured to wirelessly control the electrical connection to the electrical device.

2. The smart power plug according to claim 1 further comprising,
a measuring chip for measuring power usage information of said electrical device wherein said measured information is communicated to MCU and to outside communication contact point.

3. The smart power plug according to claim 2, wherein said measuring chip measures electrical current used by the electrical device at least 2500 times per second.

4. The smart power plug according to claim 3, wherein said measuring chip measures electrical current used by the electrical device at least 4000 times per second.

5. The smart power plug according to claim 2, wherein said wireless communication is realized through a short range communication protocol.

6. The smart power plug according to claim 5, wherein the short range communication protocol is selected from ANT+, Bluetooth, Cellular, IEEE 802.15.4, IEEE 802.22, ISA 100a, Infrared (IrDA). ISM band, NFC, RFID, 6LoWPAN, UWB, Wi-Fi, Wireless HART, WirelessHD, WirelessUSB, Zigbee and Z-Wave.

7. The smart power plug according to claim 6, wherein said short range communication protocol is Wi-Fi.

8. The smart power plug according to claim 2 further comprising
a surge protection circuit configured to protect a power surge from said power source; and
a zero crossing circuit configure to control timing of the electrical connection control by said relay control circuit.

9. The smart power plug according to claim 2, further comprising
said power cord further comprising one or more communication cable; and
a serial communication unit configured to communicate with a control unit of said electrical device through said communication cable;

10. The smart power plug according to claim 9, further comprising an isolation unit between said serial communication unit and said MCU.

11. The smart power plug according to claim 9, wherein said distal end of said power cord is connected to a female power plug and a UBS plug or a female power plug integrated with a communication port.

12. The smart power plug according to claim 9, wherein the electrical device is water heating matt.

13. A smart power plug integrated with a wireless control unit for controlling and monitoring an electrical device, comprising a housing for said wireless control unit with first and second ends, wherein said first end is connected to a male power plug configured to receive electrical power from a power source via electrical wires and said second end is connected to a power cord with a proximal end and a distal end, said distal end configured to be connected to an electrical device; said wireless control unit comprising
a micro controller unit (MCU) connected to a relay control circuit and a wireless network module;
said relay control circuit configured to control electrical connection between said power source and said electrical device
said wireless network module enables wireless communication between said smart power plug and an outside communication contact point wherein said wireless network module is configured to encrypt and modulate information received from said MCU and to communicate an operational instruction received from said outside communication contact point to said MCU;
an AC-DC converting circuit configured to convert AC electricity received from said first terminal to DC power, which is provided to said MCU and said wireless network module
a measuring chip for measuring power usage information of said electrical device wherein said measured information is communicated to MCU; and
a serial communication unit configured to communicate with a control unit of said electrical device through said communication cable
wherein said serial communication unit allows said MCU to control said electrical device based on said instruction information received from the wireless network module and said smart power plug is configured to wirelessly control and monitor the electrical device.

14. The smart power plug according to claim 13, further comprising an isolation unit between said serial communication unit and said MCU.

15. The smart power plug according to claim 13, wherein said distal end of said power cord is connected to a female power plug and a UBS plug or a female power plug integrated with a communication port.
